(19) United States
(12) Patent Application Publication
(10) Pub. No.: US 2023/0170909 A1
(43) Pub. Date: Jun. 1, 2023

(54) MEMRISTOR AIDED LOGIC (MAGIC) USING VALENCE CHANGE MEMORY (VCM)

(71) Applicant: Technion Research & Development Foundation Limited, Haifa (IL)

(72) Inventors: Shahar KVATINSKY, Haifa (IL); Barak HOFFER, Haifa (IL)

(73) Assignee: Technion Research & Development Foundation Limited, Haifa (IL)

(21) Appl. No.: 17/916,812

(22) PCT Filed: Apr. 7, 2021
(86) PCT No.: PCT/IL2021/050399

§ 371 Date: Oct. 4, 2022

Related U.S. Application Data
(60) Provisional application No. 63/006,131, filed on Apr. 7, 2020.

(51) Int. Cl. H03K 19/1776; H03K 19/21

(52) U.S. Cl. CPC H03K 19/1776; H03K 19/21; H10N 70/026

(57) ABSTRACT

A method of using memristor aided logic (MAGIC), comprises connecting together two input and one output memristor between a bit line and a word line, each memristor having a high resistance state and a low resistance state, setting the output memristor to the low resistance state as an initiation state and then applying logic inputs to the input memristors. The output then depends on whether the logic inputs have set the output memristor to the high resistance state.

### RELATED APPLICATION/S

The present application claims the priority of U.S. Provisional Application No. 63/006,131 filed 7 Apr. 2020, the contents of which are hereby incorporated herein by reference in their entirely.

### FIELD AND BACKGROUND OF THE INVENTION

This invention is partially supported by the ERC under the European Unions Horizon 2020 Research and Innovation Programme (Grant Agreement No. 757259).

The present invention, in some embodiments thereof, relates to memristor aided logic using valence change memory and, more particularly, but not exclusively, to its use for in-memory processing.

Memristors and memristive devices are two-terminal resistors, where the resistance is changed by the electrical current. The resistance serves as a stored variable. Many emerging memory technologies, including Resistive RAM (RRAM) and CBRAM, are considered as memristors. RRAM is a bipolar device where a set voltage is applied to switch the memristor to low resistance and a reset voltage is applied to switch the memristor to high resistance. Memory applications are a primary focus of memristor research in academia and industry. Another interesting application is memristor based logic.

Stateful logic methods use the data stored in the memristors as input and the result is written to a memristor as the output of the logic gate. These techniques are useful for real in-memory computation and by that they solve the memory wall problem. Examples of such logic methods include material implication (IMPLY) and memristor-aided logic (MAGIC). Both methods can be used in a memristive crossbar, which is the structure of commonly used memristive memory. In MAGIC, unlike IMPLY, memristors for the input and output are separated, the output is written to a dedicated memristor and there are no additional devices in the periphery. The MAGIC architecture is therefore preferable over IMPLY logic in terms of area, latency, and energy.

Known limitations of these memristors include:
1. To prevent overwrite of inputs in the MAGIC gate, the magnitude of the set voltage should be at least twice the magnitude of the reset voltage. Unfortunately, many RRAM devices exhibit low set-to-reset voltage ratio (even smaller than one).
2. The MAGIC method currently supports only NOT, NAND and NOR logic gates in a crossbar.

Additional background art includes:

M. Di Ventra and F. L. Traversa, “Memcomputing: Leveraging memory and physics to compute efficiently,” Journal of Applied Physics, vol. 123, no. 18, May 2018.

M. A. Zidan, J. P. Strachan, and W. D. Lu, “The future of electronics based on memristive systems,” Nature Electronics, vol. 1, no. 1, pp. 22-29, January 2018.

D. Ielmini and H. S. Wong, “In-memory computing with resistive switching devices,” Nature Electronics, vol. 1, no. 6, pp. 333-343, June 2018.

J. Reuben, R. Ben-Hur, N. Wald, N. Talati, A. Haj Ali, P. E. Gaillardon, and S. Kvatinsky, “Memristive logic: A framework for evaluation and comparison,” Proceedings of the IEEE International Symposium on Power and Timing Modeling, Optimization and Simulation, pp. 1-8, November 2017.

S. Kvatinsky, G. Satat, N. Wald, E. G. Friedman, A. Kolodny, and U. C. Weiser, “Memristor-based material implication (IMPLY) logic: Design principles and methodologies,” IEEE Transactions on Very Large Scale Integration (VLSI) Systems, vol. 22, no. 10, pp. 2054 --- 2066, October 2014.

S. Kvatinsky, D. Belousov, S. Liman, G. Satat, N. Wald, E. G. Friedman, A. Kolodny, and U. C. Weiser, “MAGIC: Memristor-Aided loGIC,” IEEE Transactions on Circuits and Systems II: Express Briefs, vol. 61, no. 11, pp. 895-899, November 2014.

N. Wald and S. Kvatinsky, “Design methodology for stateful memristive logic gates,” Proceedings of the IEEE International Conference on the Science of Electrical Engineering, pp. 1-5, November 2016.

N. Talati, S. Gupta, P. Mane, and S. Kvatinsky, “Logic Design Within Memristive Memories Using Memristor-Aided loGIC (MAGIC),” IEEE Transactions on Nanotechnology, May 2016.

R. B. Hur and S. Kvatinsky, “Memory Processing Unit for in-memory processing,” Proceedings of the IEEE/ACM International Symposium on Nanoscale Architectures, pp. 171-172, July 2016.

A. Haj-Ali, R. Ben-Hur, N. Wald, and S. Kvatinsky, “Efficient Algorithms for In-Memory Fixed Point Multiplication Using MAGIC,” Proceedings of the IEEE International Symposium on Circuits and Systems, May 2018.

A. Haj-Ali, R. Ben-Hur, N. Wald, R. Ronen, and S. Kvatinsky, “IMAGING: In-memory algorithms for image processing,” IEEE Transactions on Circuits and Systems I: Regular Papers, vol. 65, no. 12, pp. 4258- 4271, June 2018.

G. C. Adam, B D. Hoskins, M. Prezioso, and D. B. Strukov, “Optimized stateful material implication logic for three-dimensional data manipulation,” Nano Research, vol. 9, no. 12, pp. 3914-3923, December 2016.

L. J. Yu, T. Y.Wang, L. Chen, H. Zhu, Q. Q. Sun, S. J. Ding, P. Zhou, and W. D. Zhang, “Stateful Logic Operations Implemented with Graphite Resistive Switching Memory,” IEEE Electron Device Letters, vol. 39, no. 4, pp. 607-609, February 2018.

[14] Z. Y. He, T. Y. Wang, L. Chen, H. Zhu, Q.-Q. Sun, S.-J. Ding, and D. W. Zhang, “Atomic Layer-Deposited HfAlOx-Based RRAM with Low Operating Voltage for Computing In-Memory Applications,” Nanoscale Research Letters, vol. 14, no. 1, p. 51, December 2019.

H. Bae, B. C. Jang, H. Park, S. H. Jung, H. M. Lee, J. Y. Park, S. B. Jeon, G. Son, I. W. Tcho, K. Yu, S. G. Im, S. Y. Choi, and Y. K. Choi, “Functional Circuitry on Commercial Fabric via Textile- Compatible Nanoscale Film Coating Process for Fibertronics,” Nano Letters, vol. 17, no. 10, pp. 6443-6452, September 2017.

[16] B. C. Jang, S. Y. Yang, H. Seong, S. K. Kim, J. Choi, S. G. Im, and S. Y. Choi, “Zero-static-power nonvolatile logic-in-memory circuits for flexible electronics,” Nano Research, vol. 10, no. 7, pp. 2459-2470, July 2017.

B C. Jang, Y. Nam, B. J. Koo, J. Choi, S. G. Im, S.-H. K. Park, and S. Y. Choi, “Memristive Logic-in-Memory Integrated Circuits for Energy-Efficient Flexible Electronics,” Advanced Functional Materials, vol. 28, no. 2, . 1704725, January 2018.

R. Waser, R. Dittmann, C. Staikov, and K. Szot, “Redox-based resistive switching memories nanoionic mechanisms, prospects, and challenges,” Advanced Materials, vol. 21, no. 25-26, . 2632-2663, July 2009.

F. Lentz, B. Roesgen, V. Rana, D. J. Wouters, and R. Waser, “Current compliance-dependent nonlinearity in TiO2 ReRAM,” IEEE Electron Device Letters, vol. 34, no. 8, pp. 996-998, July 2013.

C. Ho, S. C. Chang, C. Y. Huang, Y. C. Chuang, S. F. Lim, M. H. Hsieh, S. C. Chang, and H. H. Liao, “Integrated HfO2-RRAM to achieve highly reliable, greener, faster, cost-effective, and scaled devices,” Proceedings of the IEEE International Electron Devices Meeting, pp. 2.6.1-2.6.4, December 2017.

S. Y. Hu, Y. Li, L. Cheng, Z. R. Wang, T. C. Chang, S. M. Sze, and X. S. Miao, “Reconfigurable Boolean Logic in Memristive Crossbar: The Principle and Implementation,” IEEE Electron Device Letters, vol. 40, no. 2, pp. 200-203, February 2019.

A. C. Torrezan, J. P. Strachan, G. Medeiros-Ribeiro, and R. S. Williams, “Sub-nanosecond switching of a tantalum oxide memristor,” Nanotechnology, vol. 22, no. 48, November 2011.

M. J. Lee, C B. Lee, D. Lee, S. R. Lee, M. Chang, J. H. Hur, Y. B. Kim, C. J. Kim, D. H. Seo, S. Seo, U. I. Chung, I. K. Yoo, and K. Kim, “A fast, high-endurance and scalable non-volatile memory device made from asymmetric Ta2O5/TaO2-x bilayer structures,” Nature Materials, vol. 10, no. 8, pp. 625 -630, July 2011. [24] L. Goux, A. Fantini, Y. Y. Chen, A. Redolfi, R. Degraeve, and M. Jurczak, “Evidences of electrode-controlled retention properties in Ta2O5- based resistive-switching memory cells,” ECS Solid State Letters, vol. 3, no. 11, pp. Q79-Q81, September 2014.

W Kim, S. Menzel, D. J. Wouters, Y. Guo, J. Robertson, B. Roesgen, R. Waser, and V. Rana, “Impact of oxygen exchange reaction at the ohmic interface in Ta2O5-based ReRAM devices,” Nanoscale, vol. 8, no. 41, pp. 17 774-17 781, October 2016.

[26] A. Haj-Ali, R. Ben-Hur, N. Wald, R. Ronen, and S. Kvatinsky, “Not in name alone: A memristive memory processing unit for real in-memory processing,” IEEE Micro, vol. 38, no. 5, pp. 13-21, September 2018.

A. Siemon, D. Wouters, S. Hamdioui, and S. Menzel, “Memristive Device Modeling and Circuit Design Exploration for Computation-in- Memory,” Proceedings of the IEEE International Symposium on Circuits and Systems, pp. 1-5, May 2019.

Q. Chen, X. Wang, H. . Wan, and R. Yang, “A Logic Circuit Design for Perfecting Memristor-Based Material Implication,” IEEE Transactions on Computer-Aided Design of Integrated Circuits and Systems, vol. 36, no. 2, pp. 279-284, February 2017.

X.Wang, Q.Wu, Q. Chen, and Z. Zeng, “A Novel Design for Memristor-Based Multiplexer Via NOT-Material Implication,” IEEE Transactions on Computer-Aided Design of Integrated Circuits and Systems, vol. 37, no. 7, pp. 1436-1444, July 2018.

K. M. Kim and R. S. Williams, “A Family of Stateful Memristor Gates for Complete Cascading Logic,” IEEE Transactions on Circuits and Systems I: Regular Papers, vol. 66, no. 11, pp. 4348-4355, July 2019.

### SUMMARY OF THE INVENTION

The present embodiments may provide MAGIC logic gates which are stable in the sense that the inputs are preserved while providing the logically mandated output. In particular MAGIC OR, NOT (or NIMP) and XOR gates are provided.

The present embodiments may provide a stable result by initializing the output memristor in the low resistance state. The logic inputs may then be based on the set voltage for the given memristor, as opposed for example to the reset voltage.

The memristors of the current embodiments may be constructed using valence change memory (VCM) or may otherwise be compatible with CMOS logic.

According to an aspect of the present invention there is provided a method of using memristor aided logic (MAGIC), the method comprising:
connecting a first memristor between a bit line and a word line;
connecting a second memristor between said bit line and said word line;
connecting a third memristor between said bit line and said word line, each memristor having a high resistance state and a low resistance state;
setting said third memristor to said low resistance state;
applying logic inputs to said first and second memristors; and
obtaining an output from said third memristor, the output depending on whether said logic inputs have set said third memristor to said high resistance state.

The method may comprise grounding the output memristor.

The memristors may have a set voltage for switching respective memristors from said low voltage state to said high voltage state, so that the output conforms to a truth table of an OR gate, in which case at least one of said logic inputs comprises said set voltage, thereby to set said third memristor to said high resistance state.

Additionally or alternatively, the memristors may have a set voltage for switching respective memristors from said low voltage state to said high voltage state, and a reset voltage for switching respective memristors from said low voltage state to said high voltage state. The ratio between said set voltage and said reset voltage is less than two.

Additionally or alternatively, the output conforms to the truth table of a NIMP gate, the method comprising applying a first, set, voltage to a first of said input memristors and a predetermined fraction of said first, set, voltage to a second of said input memristors. The fraction may be a third.

A method according to the present embodiments may comprise:
applying a first, set, voltage to a first of said input memristors and said predetermined fraction of said first, set, voltage to a second of said input memristors; and
applying a first, set, voltage to said second of said input memristors and said predetermined fraction of said first, set, voltage to said first of said input memristors, thereby to provide an output corresponding to a truth table of an XOR gate.

In embodiments, two or more memristors are arranged in a crossbar structure, the method comprising selecting three of said plurality of memristors for a required logic operation.

In embodiments, logic inputs may be supplied in pulses, said pulses being between 5 and 100 microseconds in duration. Alternatively, the pulses may be of less than 5 microseconds in duration.

The memristors may be valence change memory -- VCM --- devices.

The memristors may be constricted using Ta₂O₅.

According to a further aspect of the present invention there is provided a memory block comprising memristor aided logic including a memristor-based logic gate, the memristor-based logic gate constructed using valence change memory -VCM- memristor devices. The memory block may comprise memristors constructed using Ta₂O_{5.}

Memristor based logic gates in the block may include amongst others, one or more OR gates, and/or one or more NIMP gates and/or one or more XOR gates.

The memristor aided logic may be arranged in a crossbar configuration having a plurality of said memristor based logic gates each connected between a bit line and a word line.

The memristor based logic gate in the crossbar configuration may be any of an OR gate, a NOR gate, a NIMP gate and an XOR gate.

The memory block itself may be a Pt/ Ta₂O₅ /W/Pt device.

Multiple memristor-based logic gates may be connected together to provide predefined logic operations, including well-known conventional logic operations such as the half-adder provided herein as an example.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE SEVERAL VIEWS OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a simplified diagram showing a schematic of a two-input MAGIC NOR/OR gate;

FIG. 2 is a chart showing results of fifty cycles of MAGIC NOR attempts measured on fabricated VCM devices;

FIG. 3 is a simplified diagram showing a schematic of a MAGIC NIMP gate;

FIG. 4 is a simplified diagram showing a MAGIC NOR implementation in a crossbar,

FIGS. 5A-C are a flow chart, a cross-section and a SEM image respectively showing Pt/Ta₂0₅/W/Pt device fabrication details according to the present invention;

FIG. 6 is a chart showing results of fifty cycles of MAGIC OR attempts;

FIG. 7 is a chart showing results of fifty cycles of MAGIC NIMP attempts,

FIG. 8 is a is a chart showing results of twenty-five cycles of a one-bit half adder implementation using MAGIC gates; and

FIG. 9 is a simplified flow chart showing operation of the logic gates according to the present embodiments.

### DESCRIPTION OF SPECIFIC EMBODIMENTS OF THE INVENTION

The present invention, in some embodiments thereof, relates to memristor aided logic using valence change memory and, more particularly, but not exclusively, to its use for in-memory processing

A method of using memristor aided logic (MAGIC) according to the present embodiments comprises connecting together two input and one output memristor between a bit line and a word line, each memristor having a high resistance state and a low resistance state, setting the output memristor to the low resistance state as an initiation state and then applying logic inputs to the input memristors. The output then depends on whether the logic inputs have set the output memristor to the high resistance state. The inputs may be the set voltages for the memristor to construct an OR gate. To construct a NIMP gate the inputs are the set voltage and a fraction of the set voltage. To construct an XOR gate, the inputs are the set voltage and a fraction in a first time slot followed by a reversal of the same across the two inputs, the fraction and the set voltage, in a second time slot. The memristors may be valence change memory devices and thus be compatible with CMOS logic.

Processing-In-Memory (PIM), suggests putting computation capabilities inside the memory. This enables intrinsic computation parallelism, avoiding the need for costly chip-to-chip transfers (in terms of performance and energy), thus yielding massively parallel, high-performance, energy-efficient processing.

Gates according to the present embodiments may provide building blocks to enable processing-in-memory for memristive devices.

The set of gates of the present embodiments are compatible with memristive devices that have low set-to-reset voltage ratio. Additionally, the method of execution according to the present embodiments reduces the number of cycles needed to perform more complex logic operations.

The present embodiments may accordingly:
1. Allow parallel processing of data in memristive memories.
2. Have no need of additional devices in the periphery of the memory.
3. Be compatible with valance change memory (VCM), a promising resistive memory technology with low set-to-reset voltage ratio.
4. Guarantee non-destructive operation, keeping the inputs of the gates unchanged.

In more detail, memristive devices have attracted much attention, in the context of both future non-volatile memories, and as computation-in-memory [1]-[4]. For binary storage and computing using memristive devices, the logical states are represented by two resistive states. Generally, the high resistive state R_{OFF} is considered as logical ‘0’ (‘OFF’) and the low resistive state R_{ON} as logical ‘1’ (‘ON’). Switching between the states is based on a voltage pulse, where V_{SET} is the threshold for switching from OFF to ON and V_{RESE}_{T} is the threshold for switching from ON to OFF.

Stateful logic gates [4] use the data stored in the memristors as input and the result is written to an output memristor as a logical state. Examples of such logic families include material implication (IMPLY) [5] and memristor-aided logic (MAGIC) [6], [7]. In the MAGIC logic family, unlike IMPLY logic, memristors for the input and output are separated, the output is written to a dedicated memristor and there are no additional devices in the periphery. The MAGIC architecture is therefore preferable over IMPLY logic in terms of area, latency, and energy [8]. Furthermore, the crossbar compatible MAGIC NOR gate is considered a promising building block for processing-in-memory architectures [9]-[11].

To the best of our knowledge, the MAGIC NOR gate, as opposed to IMPLY logic [12]-[14], has only been experimentally demonstrated on exotic polymer resistive devices [15] - [17]. These devices are not compatible with complementary metal-oxide-semiconductor (CMOS) processes.

Valence change memory (VCM) [18] is a category of CMOS-compatible bipolar resistive switching devices based on transition metal oxides as the insulating material, e.g., TiO2 [19], HfO2 [20], [21] or Ta205 [22]---[25] combined with asymmetric electrodes. Specifically, Ta₂O₅-based devices are considered a promising resistive technology because of their fast switching speed [22], relatively high endurance [23], and long retention properties [24]. However, realizing MAGIC NOR on VCM devices faces a problem, caused by a physical property. To prevent overwrite of inputs in the MAGIC NOR gate, the magnitude of the set voltage should be at least twice the magnitude of the reset voltage. Unfortunately, many VCM devices exhibit low set-to-reset voltage ratios.

In the present disclosure, we describe the obstacles in executing MAGIC NOR using VCM. Then, we propose adding two new logic gates to the MAGIC family. We describe the design methodology, and explain how these gates ensure input stability for devices with low set-to-reset voltage ratios. Finally, we experimentally demonstrate, using Ta₂O₅-based memristive devices, that the new gates produce correct and reproducible results. Additionally, we demonstrate more complex logic operations, such as half-adders, using the proposed gates as building blocks.

The present embodiments provide two logic gates in a memristive crossbar, and a method to reduce the number of cycles needed to build more complex logic operations.

Memristor Aided Logic (MAGIC) is a technique to perform in-memory computing using memristive devices. The design of a MAGIC NOR gate has been described in detail, and it serves as the basic building block for memristor based processing-in-memory architectures.

However, MAGIC NOR gate inputs stability forces a limitation on the threshold voltages: the magnitude of the set voltage must be higher than the magnitude of the reset voltage. Unfortunately, many of the current leading resistive switching technologies, particularly, valence change memory (VCM), have the opposite ratio between the threshold voltages.

In this disclosure, we demonstrate the undesirable effects of input instability. Furthermore, we introduce three new MAGIC gates for devices with low set-to-reset voltage ratio and experimentally demonstrate these gates using Pt/Ta205/W/Pt devices. The three gates, combined with constant values, are functionally complete, and can serve as building blocks for in-memory logic on VCM devices.

The circuit topologies are provided, and the topologies resemble the MAGIC gates described previously.

The initial execution step includes initializing the output memristor to low resistance. Then, evaluation is achieved by grounding the output memristor line and applying voltages at the input memristors lines. These circuits can improve performance of in-memory computing and be more feasible for some RRAM devices and technologies.

For an OR gate we use the set voltage on both input lines, for a “not implication” (NIMP) we use the set voltage on one input line and a third of the set voltage on the other.

By targeting a set event on the output (as opposed to a reset event in MAGIC), we enable the implementation of these gates on devices with low set-to-reset voltage ratio.

These gates can be used sequentially to create more complex logic operations. If we evaluate a gate with the same output memristor, without an initialization cycle, we gain an OR operation between subsequent operations. This reduces the number of cycles for more complex logic operations, such as the XOR gate that can be implemented in two cycles by alternating the inputs of a NIMP gate.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

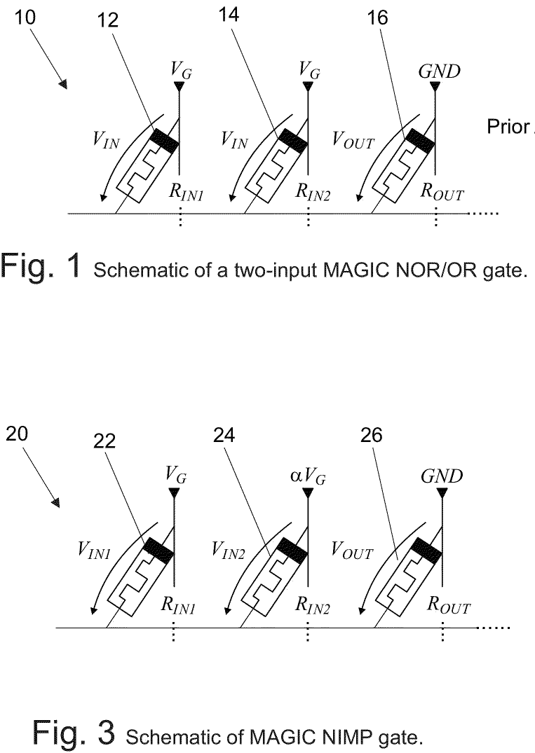

Referring now to FIG. 1, MAGIC [6] is a family of stateful memristive logic gates. A schematic of a two-input gate is shown in FIG. 1. A two-input MAGIC gate 10 consists of two input memristors (IN1 - 12, IN2 - 14), connected in parallel, and an additional memristor (OUT - 16) for the output. The schematic shows a two-input MAGIC gate within a crossbar. The operation of a MAGIC gate consists of two sequential steps. The first step initializes the output memristor to a known logical state. In the second step, a voltage V_{G} is applied across the logic gate 10. While applying V_{G}, the voltage across the output memristor 16 depends upon the logical state of the input 12, 14 and output 16 memristors, and the threshold voltages of the memristor are exploited to create a logic gate. For specific input combinations, the voltage is sufficient to change the logical state of the output memristor, i.e., the voltage across the output memristor exceeds the threshold voltage, whereas, for other input combinations, the output remains at the initialized state, i.e., the voltage across the output memristor is below the threshold voltage. According to the passive sign convention, V_{OUT} has the same sign as V_{G}, while V_{IN} has the opposite sign.

### The Magic NOR Gate

Originally, since NOR is functionally complete and MAGIC NOR can be easily mapped to a crossbar array, the MAGIC NOR gate was proposed as the basic building block for implementing in-memory logic in memristive memory processing units (mMPU) [26]. The initial execution step includes setting the output memristor to R_{ON}. Then, evaluation is achieved by grounding the OUT bitline and applying a voltage pulse V_{G} at the bitlines of the input memristors.

In the evaluation step, the voltage on the output cell is the result of a voltage divider between the input cells and the output cell,

$${V}_{O U T} \left(I N 1 , I N 2\right) = {V}_{G} \frac{{R}_{O N}}{{R}_{I N 1} \vert \vert {R}_{I N 2} + {R}_{O N}} .$$

Assuming R_{ON} << R_{OFF}, the voltage on the output as a function of the input states is obtained,

$$\begin{matrix}{V}_{O U T} \left(I N 1 , I N 2\right) = \\ \left\{\begin{matrix}{V}_{G} \frac{{R}_{O N}}{\frac{{R}_{O F F}}{2} + {R}_{O N}} \approx 0 V & I N 1 = I N 2 = 0 \\ {V}_{G} \frac{{R}_{O N}}{{R}_{O N} + {R}_{O N}} = \frac{1}{2} {V}_{G} & I N 1 \neq I N 2 \\ {V}_{G} \frac{{R}_{O N}}{\frac{{R}_{O N}}{2} + {R}_{O N}} = \frac{2}{3} {V}_{G} & I N 1 = I N 2 = 1\end{matrix}\right)\end{matrix}$$

In order to switch the output in all cases, except for the (0,0) case, V_{G} must be greater than 2V_{RESET.} This dictates the functionality of a NOR gate.

TABLE I

Input and Output Voltages for the MAGIC NOR Gate

| State | | Voltage | |
|---|---|---|---|
| R_{IN1} | R_{IN2} | V_{IN} | V_{OUT} |
| R_{OF}_{F} = 0 | R_{OFF} = 0 | -2V _{R}_{E}_{S}_{E}_{T} | 0V |
| R_{OFF} = 0 | R_{ON} = 1 | - V_{RESET} | V_{RESET} |
| R_{ON} = 1 | R_{OFF} =0 | -V_{RESET} | V_{RESET} |
| R_{ON} = 1 | R_{ON} = 1 | $- \frac{2}{3} {V}_{R E S E T}$ | $\frac{4}{5} {V}_{R E S E T}$ |

TABLE II

Set-to-Reset Voltage Ratios -- VCM Devices

| Device | [V_{SET} / V_{RESET} ] | Reference |
|---|---|---|
| Pt/Ti/TiO₂/TiN | 0.6 | [19] |
| TiN/HIO₂/Ti/TiN | 0.25-1 | [20] |
| Pt/HIO₂/TiN | 1-1.3 | [21] |
| Pt/Tn₂O₅₋ₓ/TaO₂₋ₓ/Pt | 0.5 | [23] |
| Pt/Tn₂O₅/Ta/Pt | 0.3-0.6 | [25] |
| Pt/Ta₂O₅/W/Pt | 0.4-0.6 | [25] |

### Input Stability

Another constraint of the gate is input stability. Table I lists the voltage across the input and output memristors for each input combination and demonstrates that the logical value of the input memristors can also change. Since the voltage polarity of the inputs is opposite to the voltage polarity of the output, when a reset event is targeted on the output, we risk triggering a set event on the inputs. This leads to the following physical device parameter conditions to ensure input stability,

$$\left|\frac{{V}_{S E T}}{{V}_{R E S E T}}\right| > 2.$$

Originally [6], [7], this condition was described to prevent destructive input operation and not for the functionality of the gate itself. Table II lists various different VCM memristive devices and demonstrates that they do not sustain the MAGIC NOR condition for input stability. A recent study simulated MAGIC NOR with set/reset voltage pairs that do not sustain the condition for input stability [27]. It discussed the fact that input stability is critical, since changing the inputs means that, eventually, the output will also change. The authors suggested solving this issue by finding a pulse length that is long enough to switch the output for the desired cases, but short enough to prevent unintended switching for the (0,0) case. While they succeeded in simulating this for a single gate, they eventually concluded that to execute MAGIC NOR in a crossbar, a device with VRESET « VSET is needed. Furthermore, in our view, basing the functionality of the gate on timing the pulse length is not practical for real devices because of cycle-to-cycle variations of the switching time between states.

We have conducted several experiments with fabricated VCM devices, and came to the conclusion that input stability is critical for proper logic operation. For a successful logic operation of the MAGIC NOR gate, we are interested in switching the output in all input states, except the (0,0) cases.

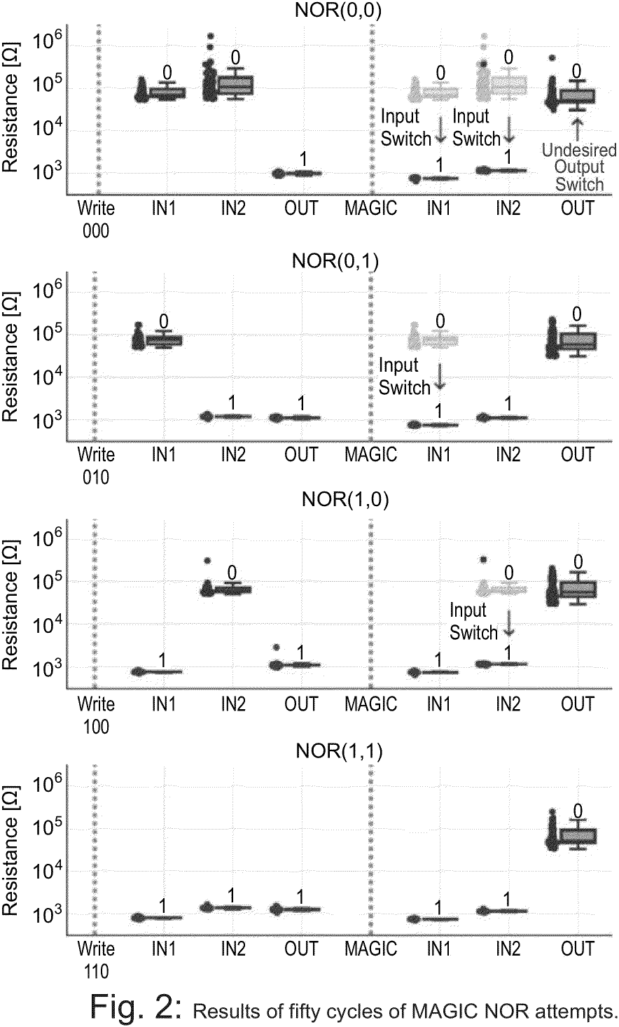

Unfortunately, as can be seen from the results in FIG. 2, the output switches for all possible states of the inputs, including the (0,0) case, resulting in logical failure. For the NOR (0,0) case, due to input instability, the inputs in fact switch over, resulting in incorrect output. More particularly, the instability of the inputs is dominant when the two inputs are initially in the R_{OFF} state. In all such cycles, at least one of the inputs switched from ROFF to RON. Additionally, for the other input cases, a drift in the resistance value was observed for the ROFF state. Both of these results can be explained by the voltage across the input cells, which was above the set threshold.

TABLE III

Input and Output Voltages for the MAGIC OR

| State | | Voltage | |
|---|---|---|---|
| R_{IN1} | R_{IN2} | V_{IN} | V_{OUT} |
| R_{OFF} = 0 | R_{O}_{F}_{F} = 0 | $- \frac{1}{3} {V}_{S E T}$ | $\frac{2}{3} {V}_{S E T}$ |
| R_{OF}_{F} = 0 | R_{ON} = 1 | 0V | V_{SET} |
| R_{ON} = 1 | R_{OFF} = 0 | 0V | V_{SET} |
| R_{ON} = 1 | R_{ON} = 1 | 0V | V_{SET} |

This instability of the input cells, can further explain the logical failure for the MAGIC NOR gate. For the (0,0) state, the voltage across the output cell is lower than the reset threshold, but the voltage across the inputs is larger than the set threshold. This causes a switching event on the inputs. After this switching event, the inputs are in one of the other possible states. This then changes the voltage across the output cell, which is now above the reset threshold, causing an undesired switching of the output. Logically, we can think about it as if we jumped from one row of the function’s truth table to another.

Considering these experimental results, we conclude that to support computation using VCM memristive devices, new MAGIC gates are required. Below, we propose three gates that operate compatibly within a memristive crossbar and fit the VCM properties.

New MAGIC gates according to the present embodiments

### Magic Or

The same structure of a two-input MAGIC, as shown in FIG. 1, can be used to implement different logic gates [7]. In the MAGIC OR gate of the present embodiments, the initialization step of the output memristor is R_{OFF} , rather than R_{ON}. Hence, a set event on the output is targeted, as opposed to a reset event in MAGIC NOR. In the evaluation step, we evaluate how the voltage across the output changes according to the voltage divider,

$${V}_{O U T} \left(I N 1 , I N 2\right) = {V}_{G} \frac{{R}_{O F F}}{{R}_{I N 1} \vert \vert {R}_{I N 2} + {R}_{O F F}} .$$

Still assuming R_{ON} << R_{OFF}, we expand this function for each case,

$${V}_{O U T} \left(I N 1 , I N 2\right) =$$

$$\left\{\begin{matrix}{V}_{G} \frac{{R}_{O F F}}{\frac{{R}_{O F F}}{2} + {R}_{O F F}} = \frac{2}{3} {V}_{G} & I N 1 = I N 2 = 0 \\ {V}_{G} \frac{{R}_{O F F}}{{R}_{O N} \vert \vert {R}_{O F F} + {R}_{O F F}} \approx {V}_{G} & I N 1 \neq I N 2 \\ {V}_{G} \frac{{R}_{O F F}}{\frac{{R}_{O N}}{2} + {R}_{O F F}} \approx {V}_{G} & I N 1 = I N 2 = 1\end{matrix}\right)$$

TABLE IV

Input and Output Voltages for the MAGIC NIMP (Lite

| State | | Voltage | | |
|---|---|---|---|---|
| R_{IN1} | R_{IN2} | V_{IN1} | V_{IN2} | V_{OUT} |
| R_{OFF} = 0 | R_{OFF} = 0 | $- \frac{5}{9} {V}_{S E T}$ | $\frac{1}{9} {V}_{S E T}$ | $\frac{4}{9} {V}_{S E T}$ |
| R_{OFF} = 0 | R_{ON} = 1 | $- \frac{2}{3} {V}_{S E T}$ | 0V | $\frac{1}{3} {V}_{S E T}$ |
| R_{ON} = 1 | R_{OFF} = 0 | 0V | $\frac{2}{3} {V}_{S E T}$ | V_{SET} |
| R_{ON} = 1 = 1 | R_{ON} | $- \frac{1}{3} {V}_{S E T}$ | $\frac{1}{3} {V}_{S E T}$ | $\frac{2}{3} {V}_{S E T}$ |

By setting V_{G} = V_{SET}, we maintain the output in R_{OFF} for the (0,0) case, and switch it to R_{ON} for any other case. This gives us the functionality of an OR gate.

A summary of the voltage drop across inputs and output for the MAGIC OR gate is presented in Table III. It shows that the voltage on the input is always 0V, except for the (0,0) case where the inputs are already in the R_{OFF} state. Hence, input stability is guaranteed and in terms of functionality the MAGIC OR gate functionality may be achieved without any limitation on the set-to-reset voltage ratio of the device.

Finally, while the present embodiments may ensure input stability for the functionality of the gate, making the gate non-destructive does force a constraint. For the cases where the output switches to R_{ON}, the amplitude of the voltage across the inputs increases during the operation. Therefore, in order to keep the inputs unchanged even after the output switched to RON, the threshold voltages may sustain the condition.

$$\left|\frac{{V}_{S E T}}{{V}_{R E S E T}}\right| < 2.$$

### B. Magic Nimp

Enabling MAGIC OR is insufficient for logic in-memory since it is not functionally complete. For a partially complete logic set, the present embodiments therefore provide another MAGIC gate by breaking the symmetry between the two inputs, as shown in FIG. 3. FIG. 3 is a schematic diagram of a MAGIC NIMP gate within a crossbar. As before, a two-input MAGIC gate 20 consists of two input memristors (INI - 22 , IN2 - 24), connected in parallel, and an additional memristor (OUT - 26) for the output.

The output cell is initialized to R_{OFF}, and in the evaluation step, V_{G} is applied to the bitline of one of the inputs, while αV_{G}(0 < α < 1) is applied to the bitline of the other input. As with other MAGIC gates, we analyze the voltage on the output according to the inputs. Since here we have different voltages for the bitlines of the two inputs, we will follow the superposition principle to calculate the total voltage across the output,

$$\begin{matrix}{V}_{O U T} \left(I N 1 , I N 2\right) = \\ {V}_{G} \frac{{R}_{I N 2} \vert \vert {R}_{O F F}}{{R}_{I N 2} \vert \vert {R}_{O F F} + {R}_{I N 1}} + α {V}_{G} \frac{{R}_{I N 1} \vert \vert {R}_{O F F}}{{R}_{I N 1} \vert \vert {R}_{O F F} + {R}_{I N 2}} .\end{matrix}$$

This can be expanded according to the state of the inputs,

$$\begin{matrix}{V}_{O U T} \left(I N 1 , I N 2\right) = \\ \left\{\begin{matrix}{V}_{G} \frac{\frac{{R}_{O F F}}{2}}{\frac{{R}_{O F F}}{2} + {R}_{O F F}} + α {V}_{G} \frac{\frac{{R}_{O F F}}{2}}{\frac{{R}_{O F F}}{2} + {R}_{O F F}} & I N 1 = I N 2 = 0 \\ {V}_{G} \frac{{R}_{O N}}{{R}_{O N} + {R}_{O F F}} + α {V}_{G} \frac{\frac{{R}_{O F F}}{2}}{\frac{{R}_{O F F}}{2} + {R}_{O N}} & I N 1 = 0 , I N 2 = 0 \\ {V}_{G} \frac{\frac{{R}_{O F F}}{2}}{\frac{{R}_{O F F}}{2} + {R}_{O N}} + α {V}_{G} \frac{{R}_{O N}}{{R}_{O N} + {R}_{O F F}} & I N 1 = 1 , I N 2 = 0 \\ {V}_{G} \frac{{R}_{O N}}{{R}_{O N} + {R}_{O N}} + α {V}_{G} \frac{{R}_{O N}}{{R}_{O N} + {R}_{O N}} & I N 1 = I N 2 = 1 ,\end{matrix}\right)\end{matrix}$$

and approximated by assuming R_{ON} << R_{OFF},

$${V}_{O U T} \left(I N 1 , I N 2\right) \approx \left\{\begin{matrix}\frac{1 + α}{3} {V}_{G} & I N 1 = I N 2 = 0 \\ α {V}_{G} & I N 1 = 0 , I N 2 = 1 \\ {V}_{G} & I N 1 = 1 , I N 2 = 0 \\ \frac{1 + α}{2} {V}_{G} & I N 1 = I N 2 = 1.\end{matrix}\right)$$

As before, by setting V_{G} === V_{SET}, we achieve switching only in the (1,0) case, resulting in the NOT functionality implication (NIMP), IN1 = IN2.

The factored voltage, αV_{G}, gives some degree of freedom for gate implementation. To minimize errors, we want minimal voltage on the output for all non-switching cases. At the same time, to ensure input stability, we want minimal voltage on the inputs, for all cases. Combining these requirements, we select

$$α = \frac{1}{3} .$$

When looking at the voltage across the inputs for each case (Table IV), it shows that the (1,1) case enforces a condition on the threshold voltages,

$$\left|\frac{{V}_{S E T}}{{V}_{R E S E T}}\right| < 3 ,$$

ie, the MAGIC NIMP gate can be implemented on devices with a low set-to-reset voltage ratio. For the (1,0) case, since we are switching the output, the voltage across the inputs changes during the operation. If want to guarantee a nondestructive operation, and keep the inputs unchanged even after the output switched to RON, the threshold voltages may sustain the condition

$$\left|\frac{{V}_{S E T}}{{V}_{R E S E T}}\right| < 2.$$

A similar logic operation was previously suggested for memristive crossbars, using a crossbar structure with a resistor in the periphery. In [28], the authors suggested a two-memristor version, where the output overwrites one of the inputs.

TABLE V

Device Measurement Parameters

| | |
|---|---|
| Parameter | Value |
| V_{SET} | -1.0 [V] |
| V_{RESET} | 2.0[V] |
| V_{READ} | -0.1[V] |
| R_{ON} | 2 - 15 [kΩ] |
| R_{OFF} | 50 - 500 [kΩ] |
| t_{SET} | 1[µs] |
| t_{RESET} | 1[µs] |

The version was simulated and used sequentially to implement more complex logic operations [29]. In [30], the authors demonstrated a three-memristor, non-destructive version, using a design methodology similar to those of the present embodiments.

### C. Two-Cycle Magic XOR

In the MAGIC NIMP gate design, we initialized the output to R_{OFF} , and targeted a set event. If the output is not initialized, and it is already in R_{ON}, a MAGIC NIMP operation will not affect its state. Namely, if we apply subsequent operations on the same output, without an initialization cycle between them, we gain an OR operation between those operations.

Thus, by running a NIMP operation twice, while alternating the inputs, we can create a two-cycle XOR logic gate:

$$\begin{matrix}I N 1 ⊕ I N 2 = I N 1 ⋅ \overline{I N 2} + I N 1 ⋅ \overline{I N 2} \\ = I N 1 ⇒ I N 2 + I N 2 ⇒ I N 1\end{matrix}$$

Referring now to Table VI below, a procedure for operating the XOR logic gate is as follows:
1) Initialize the output meristor to Roff.
2) Apply -|Vset| on IN1 bitline, -⅓ |Vset| on IN2 bitline, and ground OUT bitline.
3) Apply ⅓|Vset| on INI bitline, -|Vset| on IN2 bitline, and ground OUT bitline.

As Table VI shows, the results of this procedure for each input case yields the truth table for an XOR gate.

TABLE VI

MAGIC XOR GATE STEPS

| input | | Output | | |
|---|---|---|---|---|
| IN1 | IN2 | Step (1) Initalize | Step (2) NIMP(IN1,IN2) | Step 3 OR(OUT, NIMP(IN2,IN1) |
| ‘0’ | 0′ | ‘0’ | ‘0’ | ‘0’ |
| ‘0’ | ‘1’ | ‘0’ | ‘0’ | ‘1’ |
| ‘1’ | ‘0’ | ‘0’ | ‘1’ | ‘1’ |
| ‘1’ | ‘1’ | ‘0’ | ‘0’ | ‘0’ |

### D. Crossbar Implementation

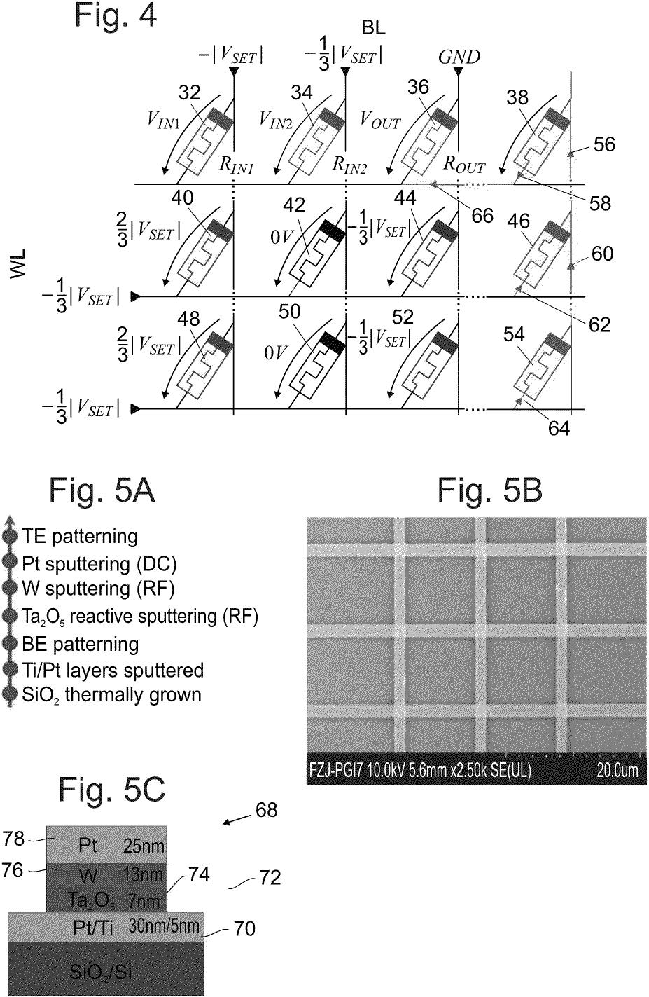

Reference is now made to FIG. 4, which is a schematic diagram that illustrates MAGIC gates in a crossbar structure 30 arranged between a word line WL and bit line BL. Cells 32, 34 and 36 participate in a logic operation. Unselected cells 44 and 52 have a constant voltage drop of -⅓ iVSET|. Unselected cells 40 and 48 have a constant voltage drop of ⅔ |VSET| and unselected cells 42 and 50 have a constant voltage drop of 0 V. Cells 38, 46 and 54 are floating cells and the possible sneak-path current passing through them are marked with arrows 56, 58, 60, 62 64 and 66. More particularly, for the gates of the present embodiments, we may assume computations in a crossbar structure, following a voltage isolation scheme to lower the sneak-path phenomenon for read and write operations [8]. For MAGIC operations, we set unselected rows to a third of the set voltage, and keep unused bitlines floating, as just described. This limits the voltage on the unselected cells to a value below the switching threshold. Having said that, the sneak path from unselected columns does have some undesired effect on the output of the gate, where current flows from the unselected cells to the output. We speculate that given the total resistance of cells and wires, this effect is very small and can be mitigated by minor adjustments to the input voltages.

### EXPERIMENTS

Reference is now made to FIGS. 5A and 5B, which show a procedure for construction and a cross-sectional diagram of a crossbar structure constructed using the procedure for the present embodiments. Specifically, FIG. 5A is a flow chart of successive procedures for manufacturing a VCM logic device according to the present embodiments. FIG. 5B is a simplified diagram showing a schematic cross section of experimental split conditions, and FIG. 5C is a scanning electron microscope image of the VCM device in passive crossbar configuration In cross-section 68, 5 nm-thick Titanium (Ti) and 30 nm-thick Platinum (Pt) layers 72 were deposited by sputtering on a thermally grown 450 nm-thick SiO2 layer on Si substrate 70. Next, photolithography and dry-etching processes were used to pattern the Pt layer as bottom electrode. After the patterning, 7 nm-thick Ta₂O₅ 74 was deposited by reactive sputtering under a process gas mixture of argon (77%) and oxygen (23%) with an RF power of 116 W at a chamber pressure of 2.3_10-2 mbar. Without breaking the vacuum, a 13 nm-thick W 76 and a 25 nm-thick Pt layer 78 were deposited by RF and DC sputtering, respectively. All deposition processes were performed at room temperature. To pattern the top electrode, photolithography with positive photo-resist was applied. After the photo-resist development, the top electrode was etched down with Reactive Ion Beam Etching (RIBE). The result is a Pt/Ta2O5/W′/Pt VCM device as shown in cross-section in FIG. 5B. An SEM image of the patterned passive crossbar structure of the memristive device is shown in FIG. 5C. The experiments were managed using Keysight’s B1530 WGFMU for voltage pulse control, a probe station and an automated script to perform write, read, and MAGIC operations on the cells. The measured device parameters and selected timing conditions are presented in Table VI.

### Functionality & Robustness

For each gate (NOR, OR, XOR, NIMP), we tested the four input combinations and measured the output For each input pattern, the test protocol was as follows:
1) Apply write pulses to set the inputs to their desired state and the output to an initial state (R_{OFF} or R_{ON}).
2) Read the resistances of the inputs and output.
3) Apply the MAGIC pulse.
4) Read the resulting resistances of the output and the inputs.

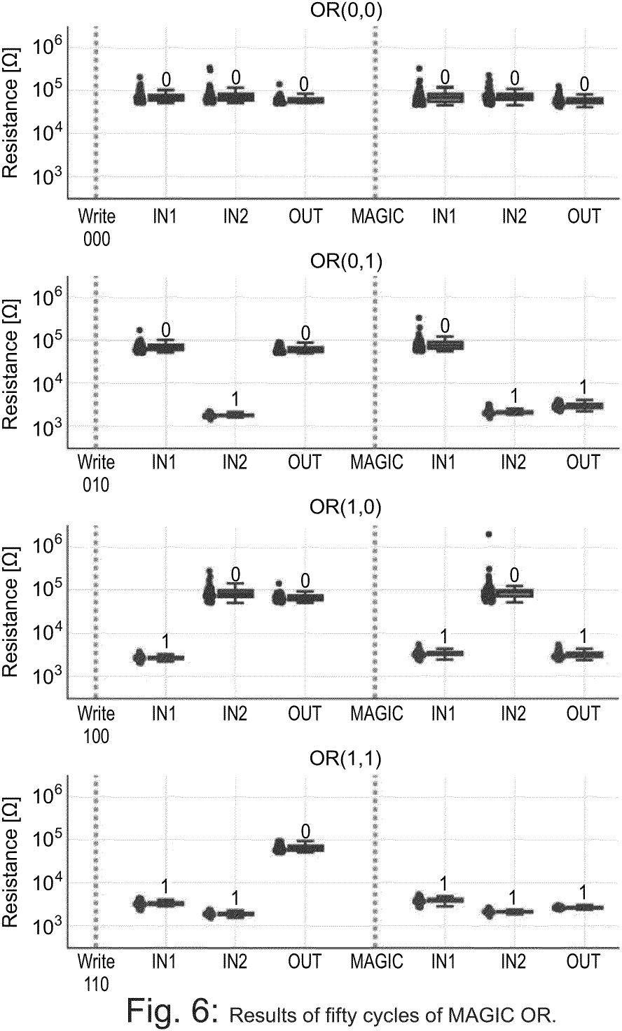

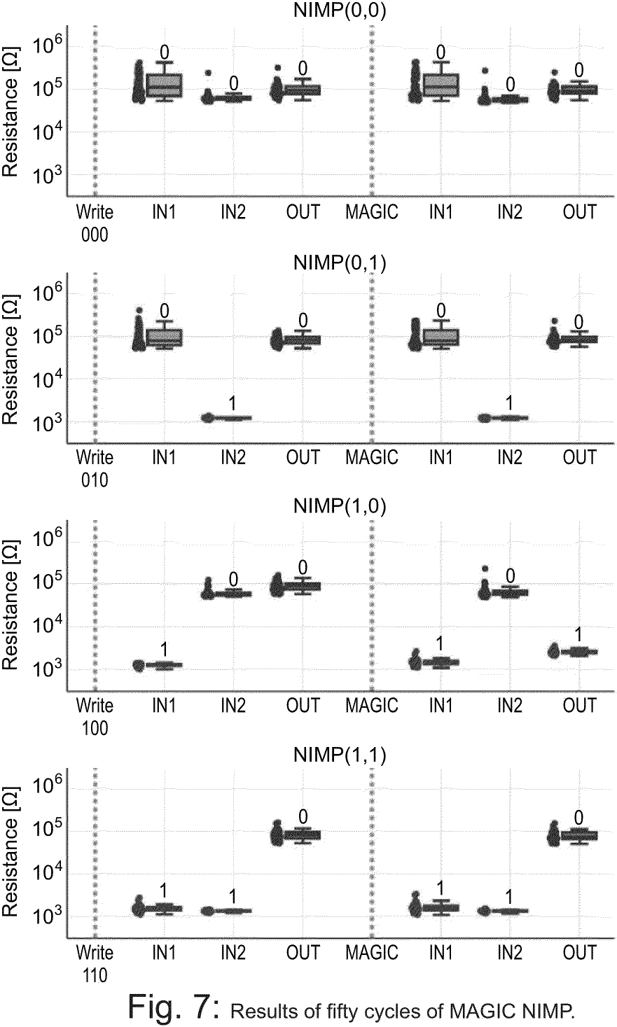

Each gate was tested for 50 cycles. FIGS. 2,6,7 present the results. The x-axis represents the cell state or an operation (initialization or gate evaluation) and the y-axis represents the resistance in a logarithmic scale. The value read in each cycle is plotted as a scatter and a median box By comparing the resistance of the output cell before and after the MAGIC pulse, we can see the switching event, if it occurs. FIG. 6 shows the result of applying 50 cycles to the MAGIC OR gate measured on a VCM device fabricated according to FIGS. 5A - 5C. The results show correct logic operation and exhibit input stability. FIG. 7 shows the result of applying 50 cycles to the MAGIC NIMP gate measured on the same VCM device fabricated according to FIGS. 5A - 5C. The results again show correct logic operation and exhibit input stability.

The results for the MAGIC OR (FIG. 6) and MAGIC NIMP (FIG. 7), thus show correct logic operation and exhibited input stability. Additionally, although there was some resistance variation, which is common for these devices, the general logic value remains correct and there is always a distinguishable margin between the resistances of the two logical states.

### Timing

Several attempts were made in order to find the minimal pulse size for performing the logic operations. Successful results were obtained with pulse size varying from 5 µs to 100 µs. Since this is an experimental setup, we speculate that for a complete integrated design, even shorter pulses will work. Furthermore, the fact that longer pulses also show working results, suggests robustness of the gates and stability of the inputs.

### Adder

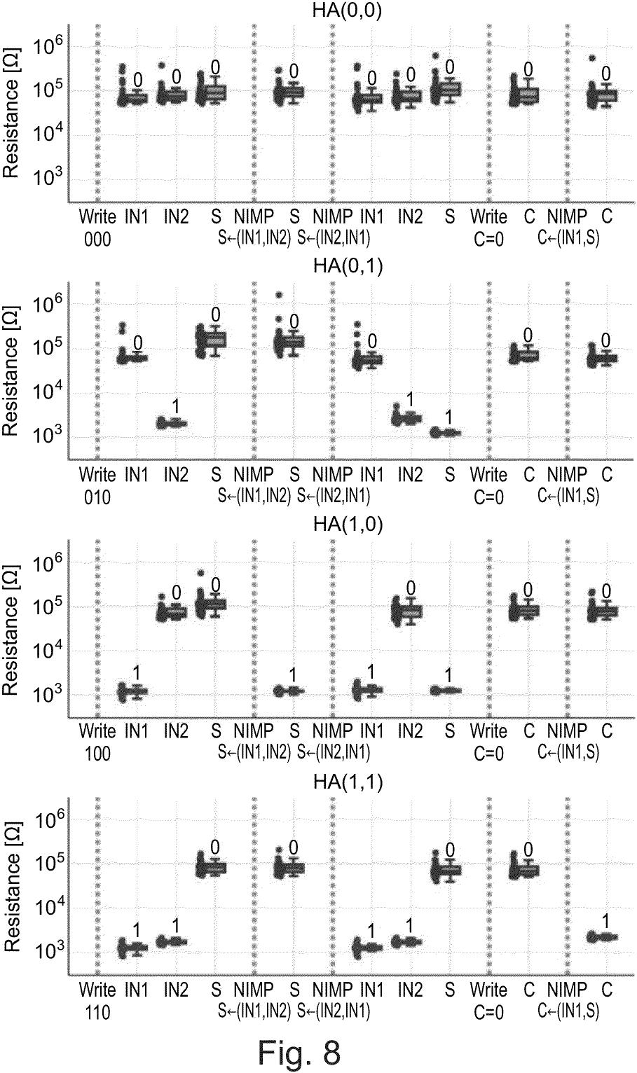

To show the performance of the proposed gates as a building block for more complex operations, a 1-bit half adder implementation was built, with the results shown in FIG. 8. Using the previously described XOR implementation, we get the sum output:

$${S}_{H A} = I N 1 ⊕ I N 2$$

This sum can be further used to obtain the carry output:

$${C}_{H A} = I N 1 ⋅ I N 2 = I N 1 ⋅ \overline{\left(I N 1 ⊕ I N 2\right)} = I N 1 ⇒ {S}_{H A}$$

The results in FIG. 8 show correct logic operation of the proposed 1-bit half-adder for 25 cycles. This demonstrates use of the output of one MAGIC operation as an input for another. Furthermore, this operation can be combined in consecutive cycles to create a full-adder with just 6 MAGIC cycles (and 3 initialization cycles):

$$\begin{matrix}{S}_{F A} = {S}_{H A} ⊕ {C}_{I N} \\ {C}_{F A} = {C}_{H A} + {C}_{I N} ⇒ {S}_{F A}\end{matrix}$$

To summarize, the present embodiments may provide three additional logic gates to the MAGIC family. These gates ensure input stability for devices where the set voltage is smaller than the reset voltage. The design and usage of these gates in VCM devices are detailed and demonstrated on fabricated devices. Additionally, we demonstrate more complex logic operations, by using the proposed gates as building blocks.

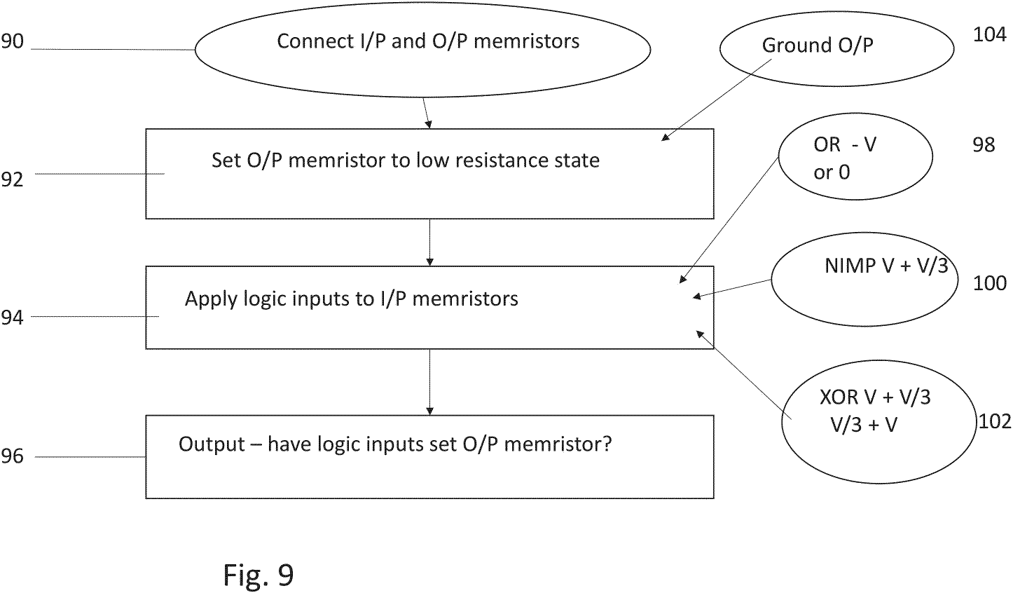

Reference is now made to FIG. 9, which is a simplified flow chart illustrating the basic operation of the logic gates according to the present embodiments

The operation of the logic gates of the present embodiments, using memristor aided logic (MAGIC) as discussed herein comprises obtaining two input and one output memristor, which would typically be connected between the word line and the bit line of a memory block - box 90. As noted, the memristors having a high resistance state and a low resistance state, and the output memristor is set initially to the low resistance state - box 92. That is to say the low resistance state is the initial state prior to carrying out the logic operation. The logic inputs are then applied to the input memristors - box 94,and the output is obtained from the output memristor, depending on whether the logic inputs have set the output memristor to the high resistance state or whether the output memristor has remained in the low resistance state

The inputs may be combinations of 1s and 0’s for the OR gate - 98, a 1 or 0 and a fraction thereof for the NIMP gate - 100 and a 1 or 0 and a fraction thereof, followed by a reversal of the same, for the XOR gate - 102.

The output memristor may optionally be grounded - 104.

It is expected that during the life of a patent maturing from this application many relevant logic gates will be developed and the scopes of these and other terms used herein are intended to include all such new technologies a priori.

The terms “comprises”, “comprising”, “includes”, “including”, “having” and their conjugates mean “including but not limited to”.

The term “consisting of” means “including and limited to”.

As used herein, the singular form “a”, “an” and “the” include plural references unless the context clearly dictates otherwise.

It is appreciated that certain features of the invention, which are, for clarity, described in the context of separate embodiments, may also be provided in combination in a single embodiment and the present description is to be construed as if such embodiments are explicitly set forth herein. Conversely, various features of the invention, which are, for brevity, described in the context of a single embodiment, may also be provided separately or in any suitable subcombination or may be suitable as a modification for any other described embodiment of the invention and the present description is to be construed as if such separate embodiments, subcombinations and modified embodiments are explicitly set forth herein. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

1. A method of using memristor aided logic (MAGIC), the method comprising:
connecting a first memristor between a bit line and a word line;
connecting a second memristor between said bit line and said word line;
connecting a third memristor between said bit line and said word line, each memristor having a high resistance state and a low resistance state;
setting said third memristor to said low resistance state;
applying logic inputs to said first and second memristors; and
obtaining an output from said third memristor, the output depending on whether said logic inputs have set said third memristor to said high resistance state.

2. The method of claim 1, comprising grounding the output memristor.

3. The method of claim 1, the memristors having a set voltage for switching respective memristors from said low voltage state to said high voltage state, wherein the output conforms to a truth table of an OR gate, and wherein at least one of said logic inputs comprises said set voltage, thereby to set said third memristor to said high resistance state.

4. The method of claim 1, the memristors having a set voltage for switching respective memristors from said low voltage state to said high voltage state, and a reset voltage for switching respective memristors from said low voltage state to said high voltage state, and wherein a ratio between said set voltage and said reset voltage is less than two.

5. The method of claim 1, wherein the output conforms to the truth table of a NIMP gate, the method comprising applying a first, set, voltage to a first of said input memristors and a predetermined fraction of said first, set, voltage to a second of said input memristors.

6. The method of claim 5, wherein said fraction is a third.

7. The method of claim 5, comprising:
applying a first, set, voltage to a first of said input memristors and said predetermined fraction of said first, set, voltage to a second of said input memristors;
applying a first, set, voltage to said second of said input memristors and said predetermined fraction of said first, set, voltage to said first of said input memristors, thereby to provide an output corresponding to a truth table of an XOR gate.

8. The method of claim 1, wherein a plurality of memristors are arranged in a crossbar structure, the method comprising selecting three of said plurality of memristors for a required logic operation.

9. The method of claim 1, comprising providing said logic inputs in pulses, said pulses being between 5 and 100 microseconds in duration.

10. The method of claim 1, comprising providing said logic inputs in pulses, said pulses being of less than 5 microseconds in duration.

11. The method of claim 1, wherein said memristors are valence change memory - VCM - devices.

12. The method of claim 1, wherein said memristors are constructed using Ta₂O₅.

13. A memory block comprising memristor aided logic including a memristor-based logic gate, the memristor-based logic gate constructed using valence change memory -VCM- memristor devices.

14. The memory block of claim 13, wherein said memristors are constructed using Ta₂O₅.

15. The memory block of claim 13, wherein said memristor based logic gate is one member of the group consisting of an OR gate, a NIMP gate and an XOR gate.

16. The memory block of claim 13, wherein said memristor aided logic is arranged in a crossbar configuration having a plurality of said memristor based logic gate between a bit line and a word line.

17. The memory block of claim 16, wherein one memristor based logic gate of said plurality of memristor-based logic gates in said crossbar configuration is one member of the group consisting of an OR gate, a NOR gate, a NIMP gate and an XOR gate.

18. The memory block of claim 13 , being a Pt/ Ta₂O₅ /W/Pt device.

19. The memory block of claim 13 , wherein a plurality of said memristor-based logic gates are connected together to provide a half-adder.
